(19) United States
(12) Patent Application Publication
(10) Pub. No.: US 2010/0052171 A1
(43) Pub. Date: Mar. 4, 2010

(54) CU WIRE IN SEMICONDUCTOR DEVICE AND PRODUCTION METHOD THEREOF

(75) Inventors: Hirotaka Ito, Hyogo (JP); Takashi Onishi, Hyogo (JP); Mikako Takeda, Hyogo (JP); Masao Mizuno, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA KOBE SEIKO SHO (KOBE STEEL, Ltd), Kobe-shi (JP)

(21) Appl. No.: 12/515,538

(22) PCT Filed: Nov. 19, 2007
(86) PCT No.: PCT/JP07/72417

§ 371 Date: May 20, 2009

(30) Foreign Application Priority Data
Nov. 28, 2006 (JP) 2006-320572
Oct. 12, 2007 (JP) 2007-267180

(51) Int. Cl. H01L 23/532; H01L 21/768

(52) U.S. Cl. 257/751; 438/643; 257/E23.161; 257/E21.584

(57) ABSTRACT

A Cu wire in a semiconductor device according to the present invention is a Cu wire embedded into wiring gutters or interlayer connective channels formed in an insulating film on a semiconductor substrate and the Cu wire comprises: a barrier layer comprising TaN formed on the wiring gutter side or the interlayer connective channel side; and a wire main body comprising Cu comprising one or more elements selected from the group consisting of Pt, In, Ti, Nb, B, Fe, V, Zr, Hf, Ga, Tl, Ru, Re, and Os in a total content of 0.05 to 3.0 atomic percent. The Cu wire in a semiconductor device according to the present invention is excellent in adhesiveness between the wire main body and the barrier layer.

### TECHNICAL FIELD

The present invention: relates to a semiconductor device; more specifically, relates to a Cu wire in a semiconductor device such as a Si semiconductor device represented by a ULSI (Ultra Large Scale Integrated-Circuit) for example and a method for forming the Cu wire.

### BACKGROUND ART

In recent years, a design rule is getting severer in order to satisfy the requirements for high integration and high-speed signal propagation of an LSI (Large Scale Integrated-Circuit) and a wiring pitch, a wire width, distance between wires, and an interlayer connective channel (via) to connect wires to each other have been contracted.

Further, studies have been done for realizing wiring of a multilayered structure to cope with the high integration of a semiconductor device and the ratio of the depth to the width (depth/width) of a wiring gutter (trench) and the ratio of the depth to the width (depth/width) of an interlayer connective channel to connect a wire on an upper layer to a wire on a lower layer increase more and more.

Moreover, the resistance of a wire itself increases in proportion to the miniaturization and the high integration of a wiring circuit and thus the delay of signal transmission is caused. To cope with the problem, attempts have been done on forming Cu wiring with a wiring material comprising Cu as the main material (hereunder referred to as a Cu type wiring material occasionally) as a wiring material that can reduce electrical resistance more than a conventional wiring material comprising Al as the main material (hereunder referred to as an Al type wiring material occasionally).

As a method for forming Cu wiring of a multilayered structure, damascene interconnect technology is known. The technology is the method of forming Cu wiring by forming wiring gutters and interlayer connective channels in an insulating film formed on a semiconductor substrate, covering the openings with a Cu type wiring material comprising pure Cu or Cu alloy, thereafter heating and pressurizing the Cu type wiring material, thereby fluidizing the Cu type wiring material, and embedding the Cu type wiring material in the wiring gutters and the interlayer connective channels. Here, an excessive Cu type wiring material not embedded into the wiring gutters and the interlayer connective channels is removed by chemical mechanical polishing (CMP).

Meanwhile, if the main body of a Cu wire directly touches an insulating film, Cu diffuses into the insulating film and deteriorates the insulation characteristics of the insulating film. Then in order to prevent Cu from diffusing into an insulating film, it is necessary to install a barrier layer between the wire main body and the insulating film. On the contrary, since heat at a high temperature of about 500° C. to 700° C. is generally applied in order to embed the Cu type wiring material formed so as to cover the openings of the wiring gutters and the interlayer connective channels into the wiring gutters and the interlayer connective channels, a barrier layer is required of exhibiting barrier properties at such a high temperature. For that reason, a metal nitride film such as a TaN film or a TiN film is used as the barrier layer. In particular, a TaN film is widely used since it exhibits better barrier properties than a TiN film at a higher temperature.

If the main body of a Cu wire is formed directly on the surface of a barrier layer consisting of ceramics such as a metal nitride film however, the interface between the barrier layer and the Cu wire acts as a main diffusion path of Cu atoms, hence Cu diffuses, and therefore it sometimes happens that voids and cracks are generated at the interface between the barrier layer and the Cu wire, the Cu wire itself breaks, or the wire migrates or deforms. Such problems are called electro migration (EM) or stress migration (SM). The electro migration means the phenomenon wherein atoms constituting a wiring material migrate by the flow of electrons and the effect of an electric field when electric current flows. The stress migration means the phenomenon wherein voids and wire breakage appear at grain boundaries by thermal activation and tensile stress even when electric current does not flow.

Moreover, the adhesiveness between the barrier layer and Cu is inferior and, if a Cu wire separates from a barrier layer and voids or the like are generated at the interface between the barrier layer and the Cu wire, the reliability of the Cu wire lowers. For that reason, it is necessary to improve the adhesiveness between a barrier layer and a Cu type wire.

Poor adhesiveness between a barrier layer and Cu is described in Patent Document 1 for example. Patent Document 1: describes that, if the adhesiveness between a barrier layer and a Cu wire is poor, exfoliation tends to occur between the barrier layer and the Cu wire; and indicates that, if exfoliation occurs, drawbacks such as wire breakage appear due to thermal stress during the operation of a semiconductor device and the reliability of the semiconductor device lowers considerably. Then Patent Document 1: describes that a barrier layer is not formed but an electrically conductive layer comprising a high-melting point metal and Cu as the main components is formed between a Cu wire and an insulating film in order to increase the reliability of a semiconductor device; and exemplifies a metallic film comprising an intermetallic compound of Ti and Cu as the electrically conductive layer. Further, Patent Document 1 describes also that a barrier layer may be formed between the electrically conductive layer and the insulating film. However, the present inventors have studied the adhesiveness of the Cu wire described in Patent Document 1 and have found that the adhesiveness between a barrier layer and a wire is insufficient and has room for improvement.

Further as stated above, in recent years, the widths of wiring gutters and interlayer connective channels are increasingly reducing and the ratios of the depth/width of the wiring gutters and the interlayer connective channels are increasing more and more and hence it is increasingly difficult to reliably embed a Cu type wiring material into the wiring gutters and the interlayer connective channels.

Patent Document 1: JP-A No. 223635/1998

### DISCLOSURE OF THE INVENTION

The present invention has been established in view of the above situation and an object of the present invention is to provide: a Cu wire having a good adhesiveness to a barrier layer comprising TaN and being formed on the surfaces of wiring gutters and interlayer connective channels; and a method for producing the Cu wire. Further, another object of the present invention is to provide: a Cu wire having a good adhesiveness to a barrier layer and being embedded into wiring gutters and interlayer connective channels in every corner even when the wiring gutters and the interlayer connective channels formed in an insulating film on a semiconductor substrate are narrow in width and deep; and a method for producing the Cu wire.

The present inventors have earnestly studied with the aim of improving the adhesiveness between a barrier layer comprising TaN and a Cu wire. As a result, the present inventors: have found that it is possible to improve the adhesiveness between a wire main body and a barrier layer by (1) comprising specific amounts of specific elements in the wire main body of a Cu wire or (2) making a Cu wire main body of pure Cu and forming an intermediate layer comprising specific amounts of specific elements between the wire main body consisting of the pure Cu and the barrier layer and also that it is possible to embed a Cu type wiring material into wiring gutters and interlayer connective channels in every corner by (3) applying heat treatment and further applying pressure if necessary when a Cu type wiring material is formed so as to cover the wiring gutters and the interlayer connective channels in the case where the wiring gutters and the interlayer connective channels are narrow in width and deep; and have completed the present invention.

That is, a Cu wire in a semiconductor device according to the present invention that has been able to solve the above problems is a Cu wire embedded into wiring gutters or interlayer connective channels formed in an insulating film on a semiconductor substrate and a gist thereof is that the Cu wire comprises: a barrier layer comprising TaN formed on the wiring gutter side or the interlayer connective channel side; and a wire main body comprising Cu comprising one or more elements selected from the group consisting of Pt, In, Ti, Nb, B, Fe, V, Zr, Hf, Ga, Tl, Ru, Re, and Os in a total content of 0.05 to 3.0 atomic percent.

Further, the above problems can also be solved with a Cu wire comprising: (1) a barrier layer comprising TaN formed on the wiring gutter side or the interlayer connective channel side; (2) a wire main body consisting of pure Cu; and (3) an intermediate layer being formed between the barrier layer and the wire main body in the manner of touching them and comprising Cu comprising one or more elements selected from the group consisting of Pt, In, Ti, Nb, B, Fe, V, Zr, Hf, Ga, Tl, Ru, Re, and Os in a total content of 0.05 to 3.0 atomic percent. The thickness of the intermediate layer is in the range of 10 to 50 nm, for example.

The wiring gutters or the interlayer connective channels may be 0.15 μm or less in width and the ratio of the depth to the width (depth/width) may be one or more.

A Cu wire in a semiconductor device according to the present invention can also be produced through: a process to form a TaN layer on the surfaces of wiring gutters or interlayer connective channels formed in an insulating film on a semiconductor substrate; and a process to form a Cu layer comprising one or more elements selected from the group consisting of Pt, In, Ti, Nb, B, Fe, V, Zr, Hf, Ga, Tl, Ru, Re, and Os in a total content of 0.05 to 3.0 atomic percent on the surface of the TaN layer by a sputtering method. When the wiring gutters or the interlayer connective channels are 0.15 μm or less in width and the ratio of the depth to the width (depth/width) is one or more and the Cu layer is hardly embedded into those, heat may be applied and further pressure may be applied if necessary when the Cu layer is embedded.

Further, a Cu wire in a semiconductor device according to the present invention can also be produced through: a process to form a TaN layer on the surfaces of wiring gutters or interlayer connective channels formed in an insulating film on a semiconductor substrate; a process to form a Cu layer comprising one or more elements selected from the group consisting of Pt, In, Ti, Nb, B, Fe, V, Zr, Hf, Ga, Tl, Ru, Re, and Os in a total content of 0.05 to 3.0 atomic percent on the surface of the TaN layer by a sputtering method; and a process to form a pure Cu layer on the surface of the Cu layer. When the wiring gutters or the interlayer connective channels are 0.15 μm or less in width and the ratio of the depth to the width (depth/width) is one or more and the pure Cu layer is hardly embedded into those, heat may be applied and further pressure may be applied if necessary when the pure Cu layer is embedded.

The present invention makes it possible to improve the adhesiveness between a wire main body and a barrier layer: either by appropriately adjusting the component composition of the wire main body of a Cu wire; or, when the Cu wire main body consists of pure Cu, by forming an intermediate layer the component composition of which is appropriately adjusted between the pure Cu and the barrier layer comprising TaN. As a result, voids or the like do not appear between the wire main body and the barrier layer and the reliability of the Cu wire can be increased. Moreover, the present invention makes it possible to embed a Cu type wiring material into wiring gutters and interlayer connective channels without hindering the adhesiveness between a barrier layer and a wire main body by applying heat and further applying pressure if necessary after the Cu type wiring material is formed so as to cover the wiring gutters and the interlayer connective channels even in the case where the wiring gutters and the interlayer connective channels are narrow in width and deep.

### BRIEF DESCRIPTION OF THE DRAWINGS

FIG. 1 comprises graphs showing the relationship between the contents of adhesiveness improving elements and the values Kₐₚₚₗ of adhesive Cu layers obtained by the MELT method. FIG. 1(b) is a graph expansively showing a part of the graph shown in FIG. 1(a) in the range of 0 to 0.2 atomic percent.

FIG. 2 is a graph showing the relationship between the contents of Fe and the values Kₐₚₚₗ of adhesive Cu layers obtained by the MELT method.

FIG. 3 is a graph showing the relationship between temperatures at normal pressure annealing treatment or at high pressure annealing treatment and the values Kₐₚₚₗ of adhesive Cu layers obtained by the MELT method.

FIG. 4 is a graph showing the relationship between the contents of adhesiveness improving elements and the values Kₐₚₚₗ of adhesive Cu layers obtained by the MELT method.

FIG. 5 is a graph showing the relationship between the thicknesses of adhesive Cu layers and the values Kₐₚₚₗ of the adhesive Cu layers obtained by the MELT method.

FIG. 6 is a graph showing the relationship between the thicknesses of adhesive Cu layers and the values Kₐₚₚₗ of the adhesive Cu layers obtained by the MELT method.

FIG. 7 is a graph showing the relationship between temperatures at normal pressure annealing treatment or at high pressure annealing treatment and the values Kₐₚₚₗ of adhesive Cu layers obtained by the MELT method.

FIG. 8 comprises graphs showing the relationship between the contents of adhesiveness improving elements and the values Kₐₚₚₗ of adhesive Cu layers obtained by the MELT method. FIG. 8(b) is a graph expansively showing a part of the graph shown in FIG. 8(a) in the range of 0 to 0.2 atomic percent.

FIG. 9 is a graph showing the relationship between the contents of adhesiveness improving elements and the values Kₐₚₚₗ of adhesive Cu layers obtained by the MELT method.

### BEST MODE FOR CARRYING OUT THE INVENTION

It is important to appropriately adjust the component composition of a layer directly touching a barrier layer in order to improve the adhesiveness between the wire main body and the barrier layer comprising TaN of a Cu wire.

That is, in the case where the layer directly touching a barrier layer is a wire main body, the best thing to do is to make the wire main body comprise Cu comprising one or more elements selected from the group consisting of Pt, In, Ti, Nb, B, and Fe or, in addition to those elements, one or more elements selected from the group consisting of V, Zr, Hf, Ga, Tl, Ru, Re, and Os in a total content of 0.05 to 3.0 atomic percent. In contrast, in the case where the wire main body consists of pure Cu, the best thing to do is to form an intermediate layer comprising Cu comprising one or more elements selected from the group consisting of Pt, In, Ti, Nb, B, and Fe or, in addition to those elements, one or more elements selected from the group consisting of V, Zr, Hf, Ga, Tl, Ru, Re, and Os in a total content of 0.05 to 3.0 atomic percent between the wire main body and a barrier layer so as to touch them.

The elements Pt, In, Ti, Nb, B, Fe, V, Zr, Hf, Ga, Tl, Ru, Re, and Os are the elements that have been found to have the function of improving the adhesiveness between a barrier layer comprising TaN and Cu (hereunder referred to as adhesiveness improving elements occasionally) as a result of various tests conducted repeatedly by the present inventors. The reason why those adhesiveness improving elements improve the adhesiveness between a barrier layer and Cu is estimated as follows.

The elements Pt, B, Ru, Re, and Os are estimated to have the function of precipitating at an interface between a barrier layer and Cu (a wire main body comprising adhesiveness improving elements or an intermediate layer comprising adhesiveness improving elements) and alleviating residual stress at the interface. It is estimated that the residual stress is imposed on the interface between a barrier layer and Cu most intensively and hence the adhesiveness of Cu to the barrier layer improves by alleviating the residual stress.

It is estimated that: the elements In, Ga, and Tl diffuse at an interface between a barrier layer and Cu and form an alloy layer of Ta and In, Ga, or Tl at the interface; and the alloy layer contributes to the improvement of the adhesiveness between the barrier layer and Cu. In particular, the melting points of In, Ga, and Tl are as low as about 156° C., 29.76° C., and 304° C., respectively, and it is estimated that they are likely to diffuse into Cu even at a low temperature lower than about 50° C. or at room temperature.

The elements Ti, Nb, Fe, V, Zr, and Hf are the elements selected in consideration of the reactivity with a barrier layer on the basis of chemical equilibrium computation and it is estimated that chemical compounds and chemical bonds are formed between those elements and Ta by the good reactivity and the adhesiveness of Cu to the barrier layer improves. For example, it is estimated that Ti forms TiN by touching the barrier layer comprising TaN and the formed TiN improves the adhesiveness of Cu to the barrier layer. It is estimated that Fe forms Fe₂Ta or FeTa₂ by touching the barrier layer comprising TaN at a low temperature side and the formed chemical compound improves the adhesiveness of Cu to the barrier layer. It is estimated that Nb forms NbN by touching the barrier layer comprising TaN and the formed NbN improves the adhesiveness of Cu to the barrier layer. It is estimated that V forms VN by touching the barrier layer comprising TaN and the formed VN improves the adhesiveness of Cu to the barrier layer. It is estimated that Zr forms ZrN by touching the barrier layer comprising TaN and the formed ZrN improves the adhesiveness of Cu to the barrier layer. It is estimated that Hf forms HfN by touching the barrier layer comprising TaN and the formed HfN improves the adhesiveness of Cu to the barrier layer.

In the case where a Cu layer comprising above adhesiveness improving elements is formed as a wire main body, it is preferable to contain particularly B and Pt in the above adhesiveness improving elements in order not only to improve the adhesiveness to a barrier layer but also not to increase the electrical resistivity of the wire itself. Further, it is preferable to contain particularly In in the above adhesiveness improving elements in order not only to improve the adhesiveness to a barrier layer but also to improve performance in embedding the Cu layer into wiring gutters and interlayer connective channels.

In contrast, in the case where a Cu layer comprising the above adhesiveness improving elements is formed as an intermediate layer, it is preferable to contain particularly Nb, Ti, and Fe in the above adhesiveness improving elements mostly in order to improve the adhesiveness to a barrier layer.

Here, in the present invention, a Cu layer comprising the above adhesiveness improving elements is referred to as an adhesive Cu layer occasionally regardless of whether the Cu layer is formed as a wire main body or as an intermediate layer.

The quantity of the adhesiveness improving elements contained in a wire main body or an intermediate layer may be in the range in a total content of 0.05 to 3.0 atomic percent. If the quantity of the adhesiveness improving elements is less than 0.05 atomic percent, it is impossible to sufficiently increase the adhesiveness between a barrier layer and a wire main body. The content of the adhesiveness improving elements is 0.05 atomic percent or more, preferably 0.5 atomic percent or more, yet preferably 1 atomic percent or more, and still yet preferably 1.5 atomic percent or more. If the adhesiveness improving elements are added excessively however, the effect is saturated and excessive elements cause the electric resistivity of a Cu wire to increase. Consequently, the content of the adhesiveness improving elements is 3.0 atomic percent or less, preferably 2.5 atomic percent or less, and yet preferably 2.0 atomic percent or less.

The thickness of an intermediate layer is not particularly limited but the thickness is preferably 10 nm or more in order to improve the adhesiveness between a barrier layer and a wire main body. The thickness is yet preferably 15 nm or more and still yet preferably 20 nm or more. If the thickness of an intermediate layer is increased excessively however, the effect of improving the adhesiveness between a barrier layer and a wire main body is saturated and hence the upper limit of the thickness of the intermediate layer may be set at about 50 nm. The upper limit is preferably 45 nm or less and yet preferably 40 nm or less.

The thickness of an intermediate layer means the minimum thickness obtained by observing a cross section of a Cu wire cut so as to expose the shape of a wiring gutter or an interlayer connective channel formed in an insulating film and measuring the thickness of the intermediate layer formed along the inner wall (a side wall or the bottom face) of the wiring gutter or the interlayer connective channel. For example, an intermediate layer: is likely to be formed on the bottom face of a wiring gutter or an interlayer connective channel; but is hardly formed on a side wall of a wiring gutter or an interlayer connective channel. Consequently, the thickness of an intermediate layer formed on a side wall of a wiring gutter or an interlayer connective channel tends to be thinner.

The type of an insulating film in which wiring gutters or interlayer connective channels are formed is not particularly limited and, for example, silicon oxide, silicon nitride, BSG (Boro-Silicate glass), PSG (Phospho-Silicate Glass), BPSG (Boro-Phospho-Silicate Glass), TEOS (SiOF), and others can be used.

Successively, a method for producing a Cu wire according to the present invention is explained. In the case where the layer directly touching a barrier layer is a wire main body, the best thing to do is to: form a TaN layer on the surfaces of wiring gutters or interlayer connective channels formed in an insulating film on a semiconductor substrate; and thereafter form an adhesive Cu layer (namely a wire main body) comprising one or more elements (adhesiveness improving elements) selected from the group consisting of Pt, In, Ti, Nb, B, Fe, V, Zr, Hf, Ga, Ti, Ru, Re, and Os in a total content of 0.05 to 3.0 atomic percent on the surface of the TaN layer by a sputtering method.

The method for forming a TaN layer is not particularly limited and a TaN layer may be formed by a sputtering method (a DC magnetron sputtering method for example), a CVD method, or another method.

The adhesive Cu layer may be formed on the surface of a TaN layer by adopting a sputtering method. By adopting a sputtering method, it is possible to easily form an adhesive Cu layer comprising adhesiveness improving elements on the surfaces of wiring gutters or interlayer connective channels covered with the TaN layer.

The sputtering method may be a (DC) magnetron sputtering method or a long throw sputtering method for example. In particular, the long throw sputtering method can preferably be adopted from the viewpoint of embedding performance as it will be stated later. The long throw sputtering method is a sputtering method of setting the distance between a wafer and a target long and, in the present invention, a method of sputtering by setting the distance at 150 mm or more is called the long throw sputtering method.

The best thing to do in order to form an adhesive Cu layer comprising adhesiveness improving elements by a sputtering method is: as the sputtering target either to use a Cu target comprising the adhesiveness improving elements or to use a chip-on target formed by attaching a Cu piece comprising the adhesiveness improving elements or a metal piece comprising the adhesiveness improving elements on the surface of a pure Cu target; and to apply sputtering under an inert gas atmosphere.

As the inert gas, for example, helium, neon, argon, krypton, xenon, or radon can be used. It is preferable to use argon or xenon and in particular argon is relatively less expensive and preferably used. Other sputtering conditions (for example, an ultimate vacuum, a sputtering gas pressure, an electric discharge power density, a substrate temperature, and distance between electrodes) are not particularly limited and may be adjusted in ordinary ranges.

The thickness of an adhesive Cu layer formed by sputtering may be changed in proportion to the depth of wiring gutters and interlayer connective channels and it is necessary to form an adhesive Cu layer having at least the same thickness as the wiring gutters and the interlayer connective channels. The upper limit of the thickness of an adhesive Cu layer is 2 μm for example. If the thickness is too heavy, the strength of an adhesive Cu layer increases and hence it comes to be difficult to embed the adhesive Cu layer into wiring gutters and interlayer connective channels even though heat and pressure are applied as it will be stated later.

In contrast, in the case where the wire main body consists pure Cu, the best thing to do is to: form a TaN layer on the surfaces of wiring gutters or interlayer connective channels formed in an insulating film on a semiconductor substrate; thereafter form an adhesive Cu layer (namely an intermediate layer) comprising one or more elements selected from the group consisting of Pt, In, Ti, Nb, B, Fe, V, Zr, Hf, Ga, Tl, Ru, Re, and Os in a total content of 0.05 to 3.0 atomic percent on the surface of the TaN layer by a sputtering method; and successively form a pure Cu layer (namely a wire main body) on the surface of the adhesive Cu layer.

The method for forming an adhesive Cu layer as an intermediate layer on the surface of a TaN layer may be the same as the case where an adhesive Cu layer is formed as a wire main body.

When an adhesive Cu layer is formed as an intermediate layer between a barrier layer and a wire main body, the thickness of the adhesive Cu layer may be about 10 to 50 nm.

The method for forming a pure Cu layer is not particularly limited and, for example, an electrolytic plating method, a chemical vapor deposition method (a CVD method), an (arc) ion plating method, a sputtering method, and other methods can be adopted. By adopting an electrolytic plating method in particular, it is possible to fill wiring gutters and interlayer connective channels gradually from the bottom with the pure Cu layer while the pure Cu is embedded. The sputtering method may be, for example, a (DC) magnetron sputtering method or a long throw sputtering method. In particular, the long throw sputtering method is preferably adopted from the viewpoint of embedding performance. The degree of purity of pure Cu may be 99 atomic percent or higher (in particular, 99.9 to 99.99 atomic percent) for example.

The thickness of a pure Cu layer may be changed in proportion to the depth of wire gutters and interlayer connective channels and a pure Cu layer having a thickness at least equal to the depth of wire gutters or interlayer connective channels may be formed. The upper limit of the thickness of a pure Cu layer is 2 μm for example. If the thickness is excessively heavy, the strength of the pure Cu layer increases and hence, in the case of forming the pure Cu layer by a sputtering method, it comes to be difficult to embed the pure Cu layer into wire gutters and interlayer connective channels even though heat and pressure are applied as it will be stated later.

For example, in the case where the width of wire gutters or interlayer connective channels is 0.15 μm or less and a ratio of the depth thereof to the width (depth/width) is one or more, if a Cu layer comprising adhesiveness improving elements or a pure Cu layer is formed as a wire main body by the sputtering method, since the wire gutters or the interlayer connective channels are narrow in width and deep, it sometimes happens that the wire main body is not completely embedded into the wire gutters or the interlayer connective channels, the wire main body makes bridges so as to cover the openings of the wire gutters or the interlayer connective channels, and voids are formed in the interior of the wire gutters or the interlayer connective channels.

In the case where a wire main body is formed by the sputtering method therefore, it is preferable to embed the wire main body into the wire gutters or the interlayer connective channels by applying pressure while applying heat. More specifically, it is preferable to apply a pressure of 150 MPa or more (yet preferably 160 MPa or more) while applying heat at 500° C. or higher (yet preferably 550° C. or higher). The upper limit of the heating temperature is about 700° C. A device to heat a wire main body to a temperature exceeding 700° C. is practically hardly available and also, if the temperature is raised too high, the electric resistivity of a Cu wire tends to increase. Moreover, a semiconductor substrate itself may deform in some cases. The upper limit of the heating temperature is preferably 650° C., and yet preferably 600° C. Here, the atmosphere at heating is not particularly limited and the aforementioned inert gas atmosphere may be sufficient for example. It is preferable to raise the pressure as high as possible. If the pressure exceeds 200 MPa however, the pressure is too high to be practical and thus the upper limit thereof is about 200 MPa, and preferably 180 MPa or lower.

Here, even though the width of wire gutters or interlayer connective channels is 0.15 μm or less and a ratio of the depth thereof to the width (depth/width) is one or more, by forming a wire main body by the long throw sputtering method, it is possible to embed the wire main body into the wire gutters or the interlayer connective channels nearly unfailingly. In the case where a wire main body is formed by the long throw sputtering method therefore, heat and pressure may not be applied but heat, pressure, or heat and pressure may be applied as occasion arises. Further, in the case where a wire main body consists pure Cu. the pure Cu layer may be formed by an electrolytic plating method and, even though the width of wire gutters or interlayer connective channels is 0.15 μm or less and a ratio of the depth thereof to the width (depth/width) is one or more, it is possible to embed the pure Cu layer into the wire gutters or the interlayer connective channels nearly unfailingly. In the case where a pure Cu layer is formed by the electrolytic plating method therefore, heat and pressure may not be applied but heat, pressure, or heat and pressure may be applied as occasion arises.

When heat is applied, any heating temperature may be adopted as long as the temperature exceeds room temperature and the heating temperature is, for example, 50° C. or higher (in particular 200° C. or higher). When pressure is applied, any pressure may be adopted as long as the pressure exceeds normal pressure and the pressure is, for example, 1 MPa or higher (in particular 10 MPa or higher).

If heat is applied while pressure is not applied however, the adhesiveness rather deteriorates. When heat is applied, the tensile stress imposed on Cu increases in comparison with the tensile strength before heating and the tensile strength acts on promoting the exfoliation of Cu from a barrier layer against the adhesiveness. In contrast, if heat and pressure are applied in combination, for example an amorphous layer comprising Cu and Ta in a mixed manner is formed at the interface between a barrier layer comprising TaN and the Cu and the adhesiveness of Cu to the barrier layer improves in proportion to the increase of the thickness of the amorphous layer. Consequently, in the case where a wire main body is formed by the long throw sputtering method too, it is preferable to apply heat and pressure.

When heat and pressure are applied, any heating temperature may be adopted as long as the temperature exceeds room temperature and the heating temperature is, for example, 50° C. or higher (in particular 200° C. or higher). When heat and pressure are applied, the pressure is, for example, 50 MPa or higher (in particular 100 MPa or higher).

The thicknesses of an adhesive Cu layer, a pure Cu layer, and a barrier layer comprising TaN, those being described above, can be adjusted by controlling the conditions for forming those layers. That is, by forming a dummy thin film by appropriately controlling the conditions for forming each of the layers beforehand and measuring the thickness of the thin film with a probe-type film thickness meter, it is possible to control the conditions for forming each of the layers and thereby adjust the film thickness.

### EXAMPLES

The present invention is hereunder explained further in detail with examples. However, the present invention is not limited to the examples below and may be carried out by appropriately modifying the examples within the range conforming to the anteroposterior tenors, and those modifications are included in the technological scope of the present invention.

### Experiment Example 1

Layered bodies are obtained by: forming TaN layers on the surfaces of silicon wafers 4 inches in diameter so that the thickness may be 50 nm by the DC magnetron sputtering method; and successively forming a pure Cu layer (No. 1 in Table 1 below) and adhesive Cu layers comprising the elements shown in Table 1 below (the remainder consisting of Cu and unavoidable impurities) by the DC magnetron sputtering method so that the thickness may be 200 nm.

An HSM-552 type sputtering apparatus made by Shimadzu Corporation is used as the sputtering apparatus and sputtering is applied by using a pure Cu target or chip-on targets. As each of the chip-on targets, a target produced by attaching 3 to 6 sheets of metal chips 5 mm square (a Cu chip comprising an intended element or a metal chip comprising an intended element) onto the surface of a pure Cu target (100 mm in diameter) functioning as the base at a position close to the position of erosion is used and the component in an adhesive Cu layer is adjusted by changing the type of the metal chips and also the composition of an adhesive Cu layer is controlled by changing the number of the metal chips or the position of the attachment.

The sputtering conditions when a TaN layer is formed are as follows; the ultimate vacuum is set at 133×10⁻⁶ Pa or lower (1×10⁻⁶ Torr or lower), a mixed gas comprising Ar and N₂ (an Ar gas comprising N₂ gas in a content of 20 volume percent) is used as the atmosphere gas during sputtering, the sputtering gas pressure is set at 667×10⁻³ Pa (5×10⁻³ Torr), the electric discharge power density is set at 2.0 W/cm² (DC), the substrate temperature is set at room temperature (Ts=20° C.), and the distance between electrodes is set at 55 mm.

The sputtering conditions when a pure Cu layer or an adhesive Cu layer is formed are as follows; the ultimate vacuum is set at 133×10⁻⁶ Pa or lower (1×10⁻⁶ Torr or lower), an Ar gas is used as the atmosphere gas during sputtering, the sputtering gas pressure is set at 267×10⁻³ Pa (2×10⁻³ Torr), the electric discharge power density is set at 3.2 W/cm² (DC), the substrate temperature is set at room temperature (Ts=20° C.), and the distance between electrodes is set at 55 mm. Here, in the case of No. 8 shown in Table 1 below, the adhesive Cu layer is formed by using a pure Cu target as the sputtering target and using a mixed gas comprising Ar and N₂ (an Ar gas comprising N₂ gas in a content of 3 volume percent) as the atmosphere gas during sputtering.

Each of the adhesiveness improving elements contained in the adhesive Cu layers formed by sputtering is determined by an ICP emission spectrometry with an ICP emission spectroscopic analyzer “ICP-8000” made by Shimadzu Corporation.

The adhesiveness of a pure Cu layer or an adhesive Cu layer to a TaN layer is evaluated for each of the obtained layered bodies by measuring the adhesive force by the MELT method. The MELT method is the method comprising the processes of coating the surface of a pure Cu layer or an adhesive Cu layer with epoxy resin and measuring the force (the adhesive force) required for peeling off the pure Cu layer or the adhesive Cu layer from a TaN layer at the interface by using stress imposed on the epoxy resin when the epoxy resin is cooled. The adhesive force is a force Gc (J/m²) required for separating a pure Cu layer or an adhesive Cu layer from a TaN layer at the interface and is represented by the formula (1) below and the value Gc can be computed with the formula (2).

$$\begin{matrix}[ Formula 1 ] & \\ Gc = \frac{\partial U}{\partial A} & ( 1 ) \\ [ Formula 2 ] & \\ Gc = \frac{{σ}_{0}^{2} h ( 1 - {v}^{2} )}{2 E} & ( 2 )\end{matrix}$$

In the formula (1), the symbol U represents the attachment force (J) of a pure Cu layer or an adhesive Cu layer to a TaN layer, and the symbol A represents the attachment area (m²). In the formula (2), the symbol σ₀ represents a residual stress in an epoxy resin layer, the symbol h the thickness of the epoxy resin layer, the symbol ν the Poisson ratio of the epoxy resin layer, and the symbol E the Young's modulus of the epoxy resin layer. The symbols h, ν, and E in the formula (2) are known values determined by the type of epoxy resin. Here, it is also possible to use a value Kₐₚₚₗ (Pa·m^{1/2}) calculated from the residual stress σ₀ (Pa) of an epoxy resin layer and the thickness h (m) of the epoxy resin layer with the formula (3) below as an index of adhesiveness. As the value Kₐₚₚₗ increases, a better adhesiveness is obtained.

[Formula 3]

Kₐₚₚₗ=σ₀\sqrt{h/2} (3)

An adhesive force is measured concretely through the following procedure. The surface of a pure Cu layer or an adhesive Cu layer formed on the surface of a silicon wafer is coated with epoxy resin 100 μm in thickness, the obtained specimen is baked at 170° C. for an hour, and thereafter the specimen is cut into a shape of 12 mm square with an outer circumference slicer (a dicing saw). The end faces of the cut specimen (the coupon) at the four corners are finished by polishing with #1,000 emery paper. The adhesive force of the pure Cu layer or the adhesive Cu layer to the TaN layer in the specimen is measured with a thin film adhesiveness tester made by FMS (FMS Laminar Series II). The obtained specimen is cooled in a chamber, the temperature at the time when the pure Cu layer or the adhesive Cu layer peels off from the TaN layer is measured, the value •₀ is obtained from the temperature, and the value Kₐₚₚₗ is computed as the adhesive force with the formula (3). The values Kₐₚₚₗ of the pure Cu layers and the adhesive Cu layers obtained by the MELT method are shown in Table 1 below.

From Table 1 below, consideration is given as follows. No. 1 is the case where a pure Cu layer is layered on a TaN layer and the cases of Nos. 2 to 7 where the adhesive Cu layers comprising one or more elements selected from the group consisting of Pt, In, Ti, Nb, B, and Fe in a content of 0.05 to 3.0 atomic percent are layered are more excellent in adhesiveness than the case of No. 1. In contrast, No. 8 is the case where an adhesive Cu layer comprising N is layered on a TaN layer and No. 9 is the case where an adhesive Cu layer comprising Sb is layered on a TaN layer, and improvement of adhesiveness of the adhesive Cu layers is not recognized in both the cases.

TABLE 1

| | Component composition of Cu alloy thin film | | |
|---|---|---|---|
| | | Content | Kₐₚₚₗ |
| No. | Alloying element | (atomic %) | (MPa · m^{1/2}) |
| 1 | — | — | 0.16 |
| 2 | Pt | 2.12 | 0.22 |
| 3 | In | 1.07 | 0.23 |
| 4 | Ti | 1.79 | 0.41 |
| 5 | Nb | 2.35 | 0.45 |
| 6 | B | 0.79 | 0.26 |
| 7 | Fe | 1.88 | 0.28 |
| 8 | N | 0.50 | 0.16 |
| 9 | Sb | 1.93 | 0.08 |

### Experiment Example 2

On the basis of Experiment example 1, layered bodies are obtained under the same conditions as Experiment example 1 except that each of the adhesive Cu layers in which the content of Pt, In, Ti, Nb, B, or Fe is adjusted (the remainder consisting of Cu and unavoidable impurities) is formed on the surface of a TaN layer.

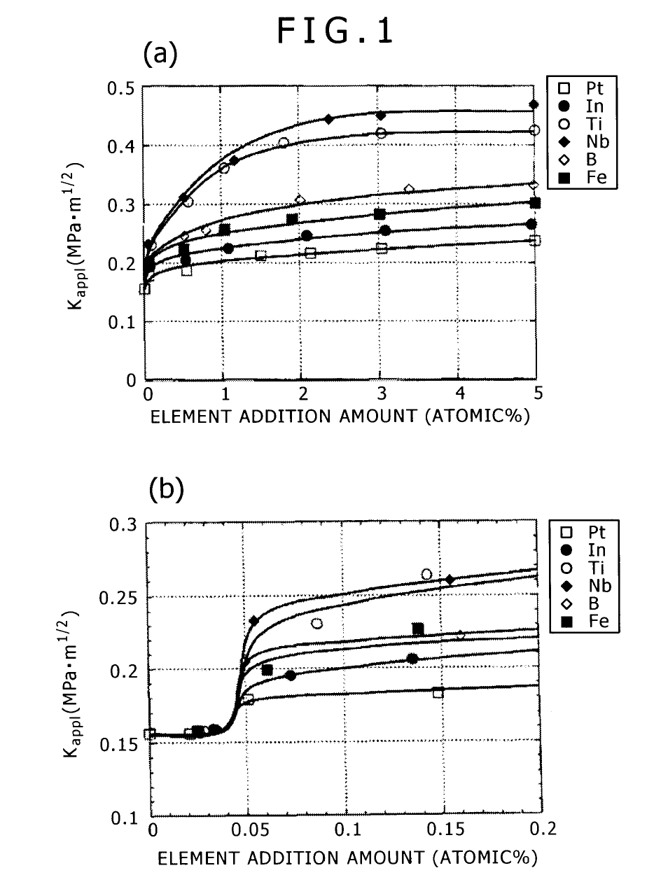

The adhesive force of the adhesive Cu layer to the TaN layer is measured for each of the obtained layered bodies under the same conditions as Experiment example 1. The relationship between the contents of adhesiveness improving elements and the values Kₐₚₚₗ of adhesive Cu layers obtained by the MELT method is shown in FIG. 1. In FIG. 1, the symbol □ represents the result of the case where Pt is contained, the symbol the result of the case where In is contained, the symbol ∘ the result of the case where Ti is contained, the symbol ♦ the result of the case where Nb is contained, the symbol ⋄ the result of the case where B is contained, and the symbol ▪ the result of the case where Fe is contained, respectively. FIG. 1(b) is a graph expansively showing a part of the graph shown in FIG. 1(a) in the range of 0 to 0.2 atomic percent.

As it is obvious from FIG. 1(a), the adhesive force of an adhesive Cu layer to a TaN layer increases as the content of an adhesiveness improving element increases. By comprising Nb or Ti as an adhesiveness improving element in particular, it is possible to increase the adhesive force more than twice in comparison with the cases where other elements are contained. Here, even when each of the adhesiveness improving elements is contained in excess of 3 atomic percent, the adhesiveness improving effect tends to be saturated.

As it is obvious from FIG. 1(b), it is understood that the adhesiveness improving effect is sharply exhibited by comprising each of the adhesiveness improving elements in a content of 0.05 atomic percent.

### Experiment Example 3

On the basis of Experiment example 1, layered bodies are obtained by: forming adhesive Cu layers in which the Fe content is adjusted (the remainder consisting of Cu and unavoidable impurities) on the surfaces of TaN layers; and thereafter either applying heat at normal pressure (hereunder referred to as normal pressure annealing treatment occasionally) or applying pressure while applying heat (hereunder referred to as high pressure annealing treatment occasionally). In the normal pressure annealing treatment, each of the layered bodies is heated from room temperature to 500° C. at a heating rate of 5° C./min in an Ar atmosphere of normal pressure (0.1 MPa), retained for 15 minutes at 500° C., and thereafter cooled to room temperature at a cooling rate of 5° C./min. In the high pressure annealing treatment, each of the layered bodies is pressurized to 150 MPa in a vacuum of 133×10⁻⁶ Pa or lower (1×10⁻⁶ Torr or lower), heated from room temperature to 500° C. at a heating rate of 15° C./min, retained for 15 minutes at 500° C., and thereafter cooled to room temperature at a cooling rate of 10° C./min.

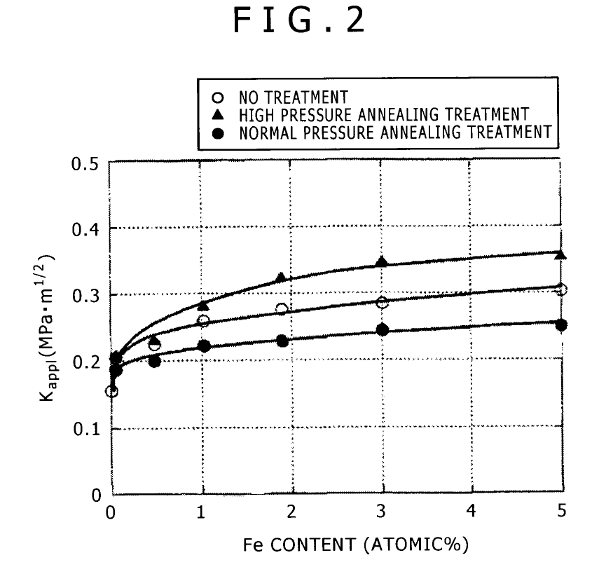

The adhesive force of the adhesive Cu layer to the TaN layer is measured for each of the obtained layered bodies under the same conditions as Experiment example 1. The relationship between the contents of Fe and the values Kₐₚₚₗ of the adhesive Cu layers obtained by the MELT method is shown in FIG. 2. In FIG. 2, the symbol represents the result of the normal pressure annealing treatment and the mark ▴ represents the result of the high pressure annealing treatment, respectively. The result of the case where neither the normal pressure annealing treatment nor the high pressure annealing treatment is applied (untreated case, the mark ∘) is also shown in FIG. 2.

As it is obvious from FIG. 2, it is understood that, even in both the cases where an adhesive Cu layer is in the state of being formed on a TaN layer (untreated case) and where normal pressure annealing treatment or high pressure annealing treatment is applied after an adhesive Cu layer is formed, the adhesive force of an adhesive Cu layer to a TaN layer increases as the Fe content increases. Here, in both the cases, even when Fe is contained in excess of 3 atomic percent, the adhesiveness improving effect tends to be saturated.

It is understood that, when normal pressure annealing treatment is applied after an adhesive Cu layer is formed, the adhesive force decreases from the level of the untreated case. In contrast, it is understood that, when high pressure annealing treatment is applied after an adhesive Cu layer is formed, the adhesive force increases from the level of the untreated case. The reason why the adhesive force decreases from the level of the untreated case when normal pressure annealing treatment is applied is presumably that both the deterioration of the adhesive force caused by heating and the improvement of the adhesive force caused by pressurizing are effective. That is, it is estimated that, in the case of the normal pressure annealing treatment, the adhesive force decreases lower than the level of the untreated case because the adhesiveness deterioration effect caused by heating has a strong effect.

### Experiment Example 4

On the basis of Experiment example 1, layered bodies are obtained by: forming adhesive Cu layers comprising Fe in a content of 1.88 atomic percent (the remainder consisting of Cu and unavoidable impurities) on the surfaces of TaN layers; and thereafter either applying heat at normal pressure (normal pressure annealing treatment) or applying pressure while applying heat (high pressure annealing treatment) in the same way as Experiment example 3.

The normal pressure annealing treatment is applied by retaining the layered bodies for 15 minutes in the state of being heated in an Ar atmosphere of normal pressure (0.1 MPa). The high pressure annealing treatment is applied by retaining the layered bodies for 15 minutes in the state of being pressurized to 150 MPa and being heated in a vacuum of 133×10⁻⁶ Pa or lower (1×10⁻⁶ Torr or lower). In both the normal pressure annealing treatment and the high pressure annealing treatment, the heating temperature is set at 200° C., 500° C., and 700° C., the heating rate is set at 5° C./min during heating, and the cooling rate is set at 5° C./min after heating.

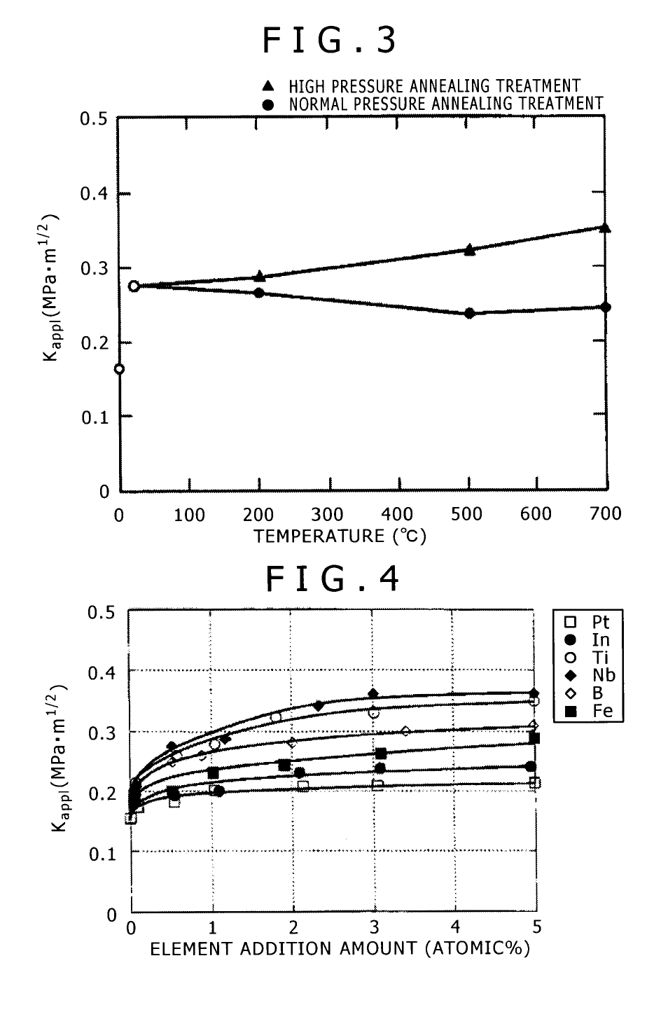

The adhesive force of the adhesive Cu layer to the TaN layer is measured for each of the obtained layered bodies under the same conditions as Experiment example 1. The relationship between the temperatures in the normal pressure annealing treatment or the high pressure annealing treatment and the values Kₐₚₚₗ of the adhesive Cu layers obtained by the MELT method is shown in FIG. 3. In FIG. 3, the symbol represents the result of the normal pressure annealing treatment and the mark ▴ represents the result of the high pressure annealing treatment, respectively. The result of the case where neither the normal pressure annealing treatment nor the high pressure annealing treatment is applied (untreated case, the mark ∘) is also shown in FIG. 3.

As it is obvious from FIG. 3, when pressure is applied, the adhesive force of an adhesive Cu layer to a TaN layer can be increased more in the case where annealing treatment is applied at a high temperature. In contrast, it is understood that, when heat is applied at normal pressure, the adhesive force of an adhesive Cu layer to a TaN layer somewhat decreases as the temperature rises.

### Experiment Example 5

On the basis of Experiment example 1, layered bodies are obtained by: forming the adhesive Cu layers 50 nm in thickness in which the content of Pt, In, Ti, Nb, B, or Fe is adjusted (the remainder consisting of Cu and unavoidable impurities) on the surfaces of TaN layers; and thereafter forming the pure Cu layers so that the thickness may be 200 nm by the DC magnetron sputtering method.

The adhesive force of the adhesive Cu layer to the TaN layer is measured for each of the obtained layered bodies under the same conditions as Experiment example 1. The relationship between the contents of the adhesiveness improving elements and the values Kₐₚₚₗ of the adhesive Cu layers obtained by the MELT method is shown in FIG. 4. In FIG. 4, the symbol □ represents the result of the case where Pt is contained, the symbol the result of the case where In is contained, the symbol ∘ the result of the case where Ti is contained, the symbol ♦ the result of the case where Nb is contained, the symbol ⋄ the result of the case where B is contained, and the symbol ▪ the result of the case where Fe is contained, respectively.

As it is obvious from FIG. 4, in the case where a pure Cu layer is formed on the surface of an adhesive Cu layer too, the adhesive force of an adhesive Cu layer to a TaN layer increases as the quantity of an adhesiveness improving element contained in the adhesive Cu layer increases. Here, even when each of the adhesiveness improving elements is contained in excess of 3 atomic percent, the adhesiveness improving effect tends to be saturated.

### Experiment Example 6

On the basis of Experiment example 1, layered bodies A are obtained by: forming the adhesive Cu layers 10 to 50 nm in thickness comprising Ti in a content of 1.79 atomic percent (the remainder consisting of Cu and unavoidable impurities) on the surfaces of TaN layers; and thereafter forming the pure Cu layers so that the thickness may be 200 nm by the DC magnetron sputtering method. Further, layered bodies B are obtained by forming the pure Cu layers so that the thickness may be 200 nm by the electrolytic plating method, in place of the DC magnetron sputtering method. The electrolytic plating is applied at the electric current density of 17 mA/cm².

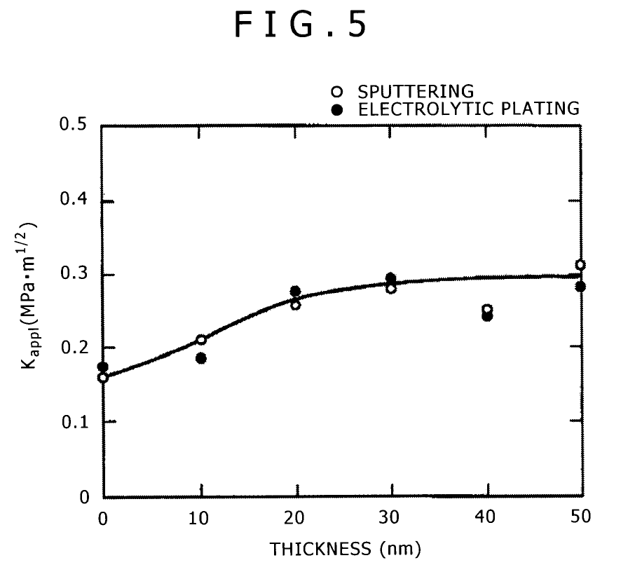

The adhesive force of the adhesive Cu layer to the TaN layer is measured for each of the obtained layered bodies A and B under the same conditions as Experiment example 1. The relationship between the thicknesses of the adhesive Cu layers and the values Kₐₚₚₗ of the adhesive Cu layers obtained by the MELT method is shown in FIG. 5. In FIG. 5, the symbol ∘ represents the result of the case where the pure Cu layers are formed by the DC magnetron sputtering method (the layered bodies A) and the symbol represents the result of the case where the pure Cu layers are formed by the electrolytic plating method (the layered bodies B), respectively.

As it is obvious from FIG. 5, it is understood that the adhesive force of an adhesive Cu layer on which a pure Cu later is formed by the electrolytic plating method to a TaN layer is scarcely different from the adhesive force of an adhesive Cu layer on which a pure Cu layer is formed by the DC magnetron sputtering method to a TaN layer.

### Experiment Example 7

On the basis of Experiment example 1, layered bodies are obtained by: forming the adhesive Cu layers 10 to 50 nm in thickness comprising Nb in a content of 2.35 atomic percent (the remainder consisting of Cu and unavoidable impurities) on the surfaces of TaN layers; thereafter forming the pure Cu layers so that the thickness may be 200 nm by the DC magnetron sputtering method; and successively applying heat at normal pressure (normal pressure annealing treatment) or applying pressure while applying heat (high pressure annealing treatment). The normal pressure annealing treatment and the high pressure annealing treatment are applied under the conditions shown in Experiment example 3.

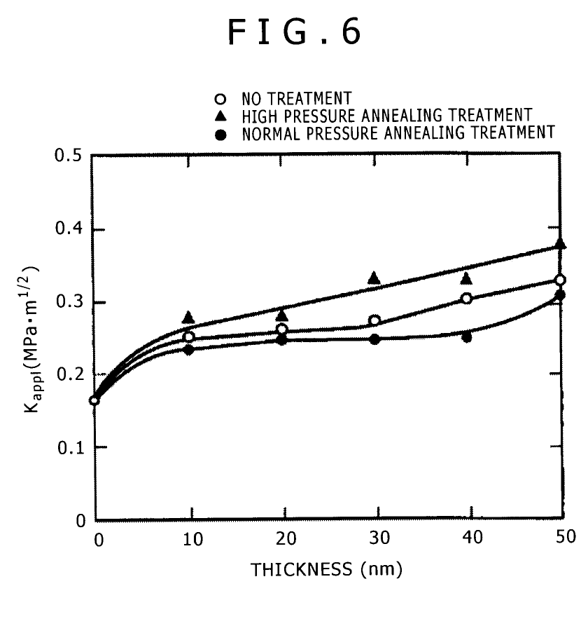

The adhesive force of the adhesive Cu layer to the TaN layer is measured for each of the obtained layered bodies under the same conditions as Experiment example 1. The relationship between the thicknesses of the adhesive Cu layers and the values Kₐₚₚₗ of the adhesive Cu layers obtained by the MELT method is shown in FIG. 6. In FIG. 6, the symbol represents the result of the normal pressure annealing treatment and the mark ▴ represents the result of the high pressure annealing treatment, respectively. The result of the case where neither the normal pressure annealing treatment nor the high pressure annealing treatment is applied (untreated case, the mark ∘) is also shown in FIG. 6.

As it is obvious from FIG. 6, it is understood that the adhesive force of an adhesive Cu layer to a TaN layer increases as the thickness of the adhesive Cu layer increases. Further, it is understood that, when the normal pressure annealing treatment is applied after an adhesive Cu layer is formed, the adhesive force decreases to a level lower than the untreated case. In contrast, it is understood that, when high pressure annealing treatment is applied after an adhesive Cu layer is formed, the adhesive force increases to a level higher than the untreated case.

### Experiment Example 8

On the basis of Experiment example 1, layered bodies are obtained by: forming the adhesive Cu layers 50 nm in thickness comprising Fe in a content of 1.88 atomic percent (the remainder consisting of Cu and unavoidable impurities) on the surfaces of TaN layers; thereafter forming the pure Cu layers so that the thickness may be 200 nm by the DC magnetron sputtering method; and successively applying heat at normal pressure (normal pressure annealing treatment) or applying pressure while applying heat (high pressure annealing treatment). The normal pressure annealing treatment and the high pressure annealing treatment are applied under the conditions shown in Experiment example 3.

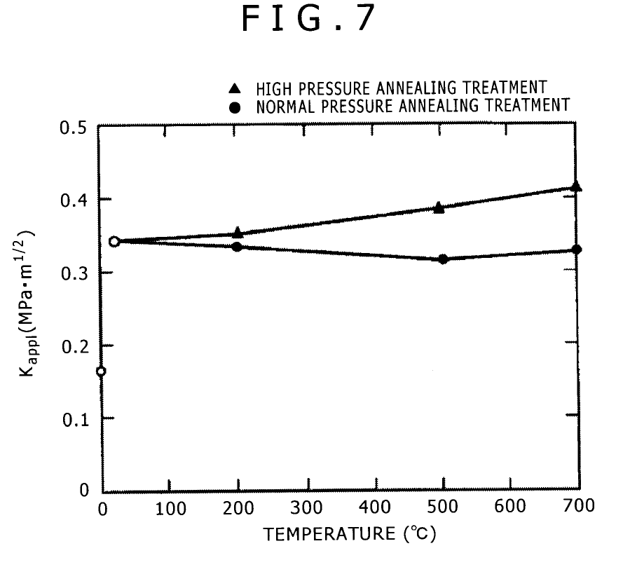

The adhesive force of the adhesive Cu layer to the TaN layer is measured for each of the obtained layered bodies under the same conditions as Experiment example 1. The relationship between the temperatures in the normal pressure annealing treatment or the high pressure annealing treatment and the values Kₐₚₚₗ of the adhesive Cu layers obtained by the MELT method is shown in FIG. 7. In FIG. 7, the symbol represents the result of the normal pressure annealing treatment and the mark ▴ represents the result of the high pressure annealing treatment, respectively. The result of the case where neither the normal pressure annealing treatment nor the high pressure annealing treatment is applied (untreated case, the mark ∘) is also shown in FIG. 7.

As it is obvious from FIG. 7, when pressure is applied, the adhesive force of an adhesive Cu layer to a TaN layer can be increased more in the case where annealing treatment is applied at a high temperature. In contrast, it is understood that, when heat is applied at normal pressure, the adhesive force of an adhesive Cu layer to a TaN layer somewhat decreases as the heating temperature rises.

### Experiment Example 9

A test element group (TEG) having vias 0.12 μm (120 nm) in diameter and 0.55 μm (550 nm) in depth formed at intervals of 450 nm in an insulating film (a TEOS film: an SiOF film) formed on the surface of a silicon wafer is used. A TaN layer is formed on the surface of the TEG so that the thickness may be 50 nm under the same conditions as Experiment example 1 by the DC magnetron sputtering method, and thereafter an adhesive Cu layer comprising Fe in a content of 1.88 atomic percent (the remainder consisting of Cu and unavoidable impurities) is formed so that the thickness may be 500 nm by the sputtering method (the CS method) or the long throw sputtering method (the LTS method).

The sputtering conditions under which an adhesive Cu layer is formed are the same as the conditions shown in Experiment example 1. The long throw sputtering conditions under which an adhesive Cu layer is formed are as follows; the ultimate vacuum is set at 133×10⁻⁶ Pa or lower (1×10⁻⁶ Torr or lower), an Ar gas is used as the atmosphere gas during sputtering, the sputtering gas pressure is set at 266×10⁻³ Pa (2×10⁻³ Torr), the electric discharge power density is set at 25 W/cm² (DC), the substrate bias voltage is set at −200 V, the substrate temperature Ts is set at 0° C., and the distance between electrodes is set at 300 mm.

After the adhesive Cu layer is formed, each of the layered bodies is obtained by applying heat at normal pressure (normal pressure annealing treatment) or applying pressure while applying heat (high pressure annealing treatment) in the same way as Experiment example 3. The normal pressure annealing treatment and the high pressure annealing treatment are applied under the conditions shown in Experiment example 4. Here, Nos. 11 and 18 in Table 2 below are the case where neither the normal pressure annealing treatment nor the high pressure annealing treatment is applied after the adhesive Cu layer is formed.

A treated TEG is processed with a focused ion beam apparatus (an FIB apparatus) so that a cross section of a via may be exposed, the cross section is observed by an SIM image of the FIB apparatus, and thereby how an adhesive Cu layer is embedded into a via (embedding performance) is investigated. The SIM image obtained from the cross section of the via is analyzed and the embedding performance is evaluated by an embedding ratio calculated with the formula (4) below. Fifteen vias are observed, the embedding ratio is calculated for each of the vias, and the embedding ratios are averaged. The embedding ratios are shown in Table 2 below.

Embedding ratio (%)=[(cross sectional area of adhesive Cu layer embedded into via)/(cross sectional area of via)]×100 (4)

As it is obvious from Table 2, it is understood that, in the case where an adhesive Cu layer is formed by the sputtering method, the adhesive Cu layer can be embedded into a via by applying heat up to 500° C. or higher and pressure up to 150 MPa. Further, in the case where an adhesive Cu layer is formed by the long throw sputtering method, when heat is applied, it is possible to completely embed the adhesive Cu layer into a via at both the normal pressure and the high pressure.

TABLE 2

| | | | Annealing treatment condition | | | |
|---|---|---|---|---|---|---|
| | Cu alloy thin film | Cu alloy thin film | Temperature | Pressure | Time | Embedding |
| No. | forming method | thickness (nm) | (° C.) | (MPa) | (min) | ratio (%) |
| 11 | CS method | 500 | Not applied | | | 60 |
| 12 | CS method | 500 | 200 | 0.1 | 15 | 62 |
| 13 | CS method | 500 | 500 | 0.1 | 15 | 70 |
| 14 | CS method | 500 | 700 | 0.1 | 15 | 76 |
| 15 | CS method | 500 | 200 | 150 | 15 | 66 |
| 16 | CS method | 500 | 500 | 150 | 15 | 92 |
| 17 | CS method | 500 | 700 | 150 | 15 | 100 |
| 18 | LTS method | 500 | Not applied | | | 100 |
| 19 | LTS method | 500 | 200 | 0.1 | 15 | 100 |
| 20 | LTS method | 500 | 500 | 0.1 | 15 | 100 |
| 21 | LTS method | 500 | 700 | 0.1 | 15 | 100 |
| 22 | LTS method | 500 | 200 | 150 | 15 | 100 |
| 23 | LTS method | 500 | 500 | 150 | 15 | 100 |
| 24 | LTS method | 500 | 700 | 150 | 15 | 100 |

CS method: Sputtering method, LTS method: Long throw sputtering method

### Experiment Example 10

On the basis of Experiment example 9, adhesive Cu layers comprising Ti in a content of 1.79 atomic percent (the remainder consisting of Cu and unavoidable impurities) are formed on the surfaces of TaN layers so that the thicknesses may be 10 to 50 nm by the sputtering method (the CS method), and pure Cu layers are formed so that the thickness may be 500 nm by the electrolytic plating method, the sputtering method (the CS method), and the long throw sputtering method (the LTS method).

The sputtering conditions when the adhesive Cu layers are formed are the same as the conditions shown in Experiment example 1. The electrolytic plating conditions, the sputtering conditions, and the long throw sputtering conditions when the pure Cu layers are formed are the same as the conditions shown in Experiment example 6, Experiment example 1, and Experiment example 9, respectively.

After the pure Cu layers are formed, each of the layered bodies is obtained by applying heat at normal pressure (normal pressure annealing treatment) or applying pressure while applying heat (high pressure annealing treatment) in the same way as Experiment example 4. The normal pressure annealing treatment is applied by retaining the layered bodies for 15 minutes in the state of being heated in an Ar atmosphere of normal pressure (0.1 MPa). The high pressure annealing treatment is applied by retaining the layered bodies for 15 minutes in the state of being pressurized to 150 MPa and being heated in a vacuum of 133×10⁻⁶ Pa or lower (1×10⁻⁶ Torr or lower). In both the normal pressure annealing treatment and the high pressure annealing treatment, the heating temperature is set at 200° C. and 500° C., the heating rate is set at 5° C./min during heating, and the cooling rate is set at 5° C./min after heating. Here, Nos. 31 to 33, 38, and 44 in Table 3 below are the case where neither the normal pressure annealing treatment nor the high pressure annealing treatment is applied after the pure Cu layers are formed.

With regard to a TEG after treatment, how an adhesive Cu layer and a pure Cu layer are embedded into a via (embedding performance) is investigated under the same conditions as Experiment example 11. The embedding ratios are shown in Table 3 below.

From Table 3, consideration is given as follows. In the cases of Nos. 31 to 37, the thicknesses of the adhesive Cu layers are reduced and the pure Cu layers are formed by the electrolytic plating method, and hence it is possible to completely embed the adhesive Cu layers and the pure Cu layers into recesses even without the application of annealing treatment. As it is obvious from the cases of Nos. 42 and 43, when a pure Cu layer is formed by the sputtering method, it is possible to embed the pure Cu layer into vias by applying pressure up to 150 MPa while being heated to 500° C. or higher. As it is obvious from the cases of Nos. 44 to 50, when a pure Cu layer is formed by the long throw sputtering method, it is possible to embed the pure Cu layer into vias even without the application of annealing treatment.

TABLE 3

| | | | | Annealing treatment condition | | | |
|---|---|---|---|---|---|---|---|
| | Cu alloy thin film | Cu alloy thin film | Pure Cu thin film | Temperature | Pressure | Time | Embedding |
| No. | forming method | thickness (nm) | forming method | (° C.) | (MPa) | (min) | ratio (%) |
| 31 | CS method | 10 | Electrolytic plating | Not applied | | | 100 |
| | | | method | | | | |
| 32 | CS method | 30 | Electrolytic plating | Not applied | | | 100 |
| | | | method | | | | |
| 33 | CS method | 50 | Electrolytic plating | Not applied | | | 100 |
| | | | method | | | | |
| 34 | CS method | 50 | Electrolytic plating | 200 | 0.1 | 15 | 100 |
| | | | method | | | | |
| 35 | CS method | 50 | Electrolytic plating | 500 | 0.1 | 15 | 100 |
| | | | method | | | | |
| 36 | CS method | 50 | Electrolytic plating | 200 | 150 | 15 | 100 |
| | | | method | | | | |
| 37 | CS method | 50 | Electrolytic plating | 500 | 150 | 15 | 100 |
| | | | method | | | | |
| 38 | CS method | 50 | CS method | Not applied | | | 65 |
| 39 | CS method | 50 | CS method | 500 | 0.1 | 15 | 68 |
| 40 | CS method | 50 | CS method | 700 | 0.1 | 15 | 69 |
| 41 | CS method | 50 | CS method | 200 | 150 | 15 | 78 |
| 42 | CS method | 50 | CS method | 500 | 150 | 15 | 100 |
| 43 | CS method | 50 | CS method | 700 | 150 | 15 | 100 |
| 44 | CS method | 50 | LTS method | Not applied | | | 98 |
| 45 | CS method | 50 | LTS method | 200 | 0.1 | 15 | 100 |
| 46 | CS method | 50 | LTS method | 500 | 0.1 | 15 | 100 |
| 47 | CS method | 50 | LTS method | 700 | 0.1 | 15 | 100 |
| 48 | CS method | 50 | LTS method | 200 | 150 | 15 | 100 |
| 49 | CS method | 50 | LTS method | 500 | 150 | 15 | 100 |
| 50 | CS method | 50 | LTS method | 700 | 150 | 15 | 100 |

CS method: Sputtering method

### Experiment Example 11

On the basis of Experiment example 1, layered bodies are obtained under the same conditions as Experiment example 1 except that adhesive Cu layers in which the content of V, Zr, Re, Ru, Hf, Ga, Os, or Tl is adjusted (the remainder consisting of Cu and unavoidable impurities) are formed on the surfaces of TaN layers. Here, since the melting point of Ga is low, it is impossible to produce a metal chip comprising the Ga element. Consequently, in the case of Ga, a Cu alloy chip comprising Ga in a content of 5 or 10 atomic percent (the remainder consisting of unavoidable impurities) is produced and a chip-on target is formed by attaching three to six sheets of the Cu alloy chips 5 mm square onto the surface of a pure Cu target (100 mm in diameter) functioning as the base at a position close to the position of erosion and used. The compositions of the adhesive Cu layers are controlled by changing the types, the numbers, and the attachment positions of the Cu alloy chips.

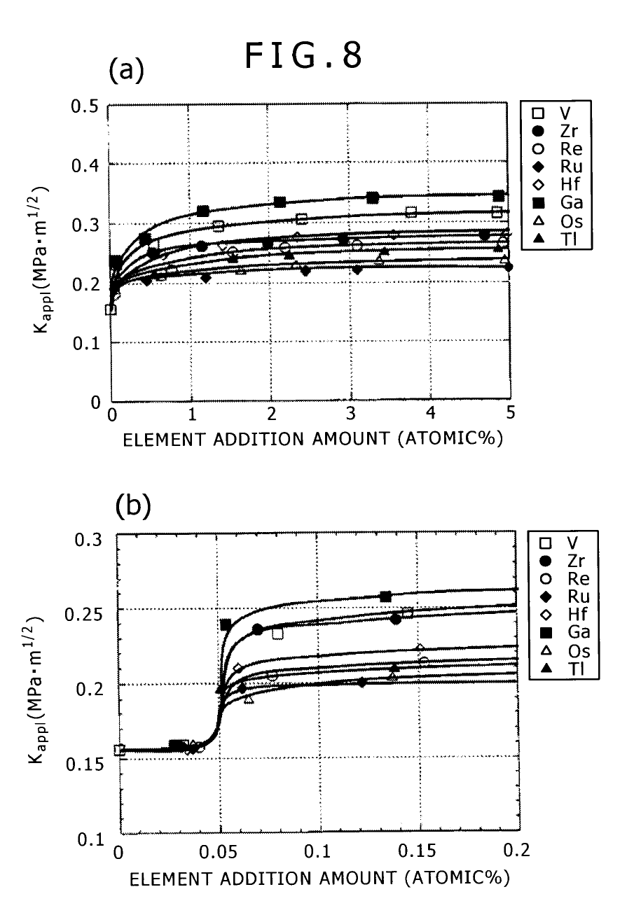

The adhesive force of the adhesive Cu layer to the TaN layer is measured for each of the obtained layered bodies under the same conditions as Experiment example 1. The relationship between the contents of the adhesiveness improving elements and the values Kₐₚₚₗ of the adhesive Cu layers obtained by the MELT method is shown in FIG. 8. In FIG. 8, the symbol □ represents the result of the case where V is contained, the symbol the result of the case where Zr is contained, the symbol ∘ the result of the case where Re is contained, the symbol ♦ the result of the case where Ru is contained, the symbol ⋄ the result of the case where Hf is contained, the symbol ▪ the result of the case where Ga is contained, the symbol Δ the result of the case where Os is contained, and the symbol ▴ the result of the case where Tl is contained, respectively. FIG. 8(b) is a graph expansively showing a part of the graph shown in FIG. 8(a) in the range of 0 to 0.2 atomic percent.

As it is obvious from FIG. 8(a), the adhesive force of an adhesive Cu layer to a TaN layer increases as the content of an adhesiveness improving element increases. Even when each of the adhesiveness improving elements is contained in excess of 3 atomic percent however, the adhesiveness improving effect tends to be saturated.

As it is obvious from FIG. 8(b), it is understood that the adhesiveness improving effect is sharply exhibited by comprising each of the adhesiveness improving elements in a content of 0.05 atomic percent.

### Experiment Example 12

On the basis of Experiment example 1, layered bodies are obtained by: forming adhesive Cu layers 50 nm in thickness in which the content of V, Zr, Re, Ru, Hf, or Ga is adjusted (the remainder consisting of Cu and unavoidable impurities) on the surfaces of TaN layers; and thereafter forming pure Cu layers so that the thickness may be 200 nm by the DC magnetron sputtering method.

Here, with regard to Ga, the compositions in the adhesive Cu layers are controlled by the procedure shown in Experiment example 11.

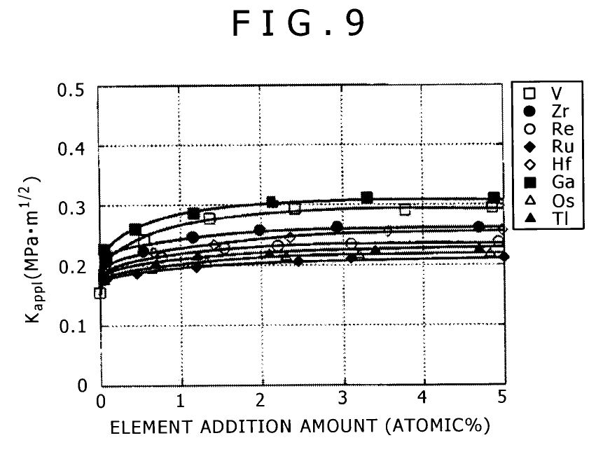

The adhesive force of the adhesive Cu layer to the TaN layer is measured for each of the obtained layered bodies under the same conditions as Experiment example 1. The relationship between the contents of the adhesiveness improving elements and the values Kₐₚₚₗ of the adhesive Cu layers obtained by the MELT method is shown in FIG. 9. In FIG. 9, the symbol □ represents the result of the case where V is contained, the symbol the result of the case where Zr is contained, the symbol ∘ the result of the case where Re is contained, the symbol ♦ the result of the case where Ru is contained, the symbol ⋄ the result of the case where Hf is contained, the symbol Δ the result of the case where Ga is contained, the symbol ▴ the result of the case where Os is contained, and the symbol A the result of the case where Tl is contained, respectively.

As it is obvious from FIG. 9, even in the case where a pure Cu layer is formed on the surface of an adhesive Cu layer, the adhesive force of an adhesive Cu layer to a TaN layer increases as the content of an adhesiveness improving element increases. Even when each of the adhesiveness improving elements is contained in excess of 3 atomic percent however, the adhesiveness improving effect tends to be saturated.

The present invention has been explained in detail in reference to specific embodiments but it is well known to those skilled in the art that the present invention can be changed and modified variously without deviating the tenor and the scope of the present invention.

Here, the present application is based on the Japanese Patent Application (JP-A No. 320572/2006) applied on Nov. 28, 2006 and the Japanese Patent Application (JP-A No. 267180/2007) applied on Oct. 12, 2007 and the whole contents are quoted by the citation.

Further, all the references cited here are taken in as a whole.

### INDUSTRIAL APPLICABILITY

The present invention makes it possible to improve the adhesiveness between a wire main body and a barrier layer: either by appropriately adjusting the component composition of the wire main body of a Cu wire; or, when the Cu wire main body consists of pure Cu, by forming an intermediate layer the component composition of which is appropriately adjusted between the pure Cu and the barrier layer comprising TaN. As a result, voids or the like do not appear between the wire main body and the barrier layer and the reliability of the Cu wire can be increased. Moreover, the present invention makes it possible to embed a Cu type wiring material into wiring gutters and interlayer connective channels without hindering the adhesiveness between a barrier layer and a wire main body by applying heat and further applying pressure if necessary after the Cu type wiring material is formed so as to cover the wiring gutters and the interlayer connective channels even in the case where the wiring gutters and the interlayer connective channels are narrow in width and deep.

1. A Cu wire in a semiconductor device, the Cu wire being embedded into wiring gutters or interlayer connective channels formed in an insulating film on a semiconductor substrate,
wherein the Cu wire comprises:
(1) a barrier layer comprising TaN formed on the wiring gutter side or the interlayer connective channel side; and
(2) a wire main body comprising Cu and one or more elements selected from the group consisting of Pt, In, Ti, Nb, B, Fe, V, Zr, Hf, Ga, Tl, Ru, Re, and Os in a total content of 0.05 to 3.0 atomic percent.

2. A Cu wire in a semiconductor device, the Cu wire being embedded into wiring gutters or interlayer connective channels formed in an insulating film on a semiconductor substrate,
wherein the Cu wire comprises:
(1) a barrier layer comprising TaN formed on the wiring gutter side or the interlayer connective channel side;
(2) a wire main body consisting of pure Cu; and
(3) an intermediate layer being formed between the barrier layer and the wire main body in the manner of touching them and comprising Cu and one or more elements selected from the group consisting of Pt, In, Ti, Nb, B, Fe, V, Zr, Hf, Ga, Tl, Ru, Re, and Os in a total content of 0.05 to 3.0 atomic percent.

3. The Cu wire according to claim 2, wherein the thickness of the intermediate layer is in the range of 10 to 50 nm.

4. The Cu wire according to claim 1, wherein the wiring gutters or the interlayer connective channels are 0.15 μm or less in width and the ratio of the depth to the width (depth/width) is one or more.

5. A method for producing a Cu wire in a semiconductor device, comprising:
forming a TaN layer on the surfaces of wiring gutters or interlayer connective channels formed in an insulating film on a semiconductor substrate; and
forming a Cu layer comprising Cu and one or more elements selected from the group consisting of Pt, In, Ti, Nb, B, Fe, V, Zr, Hf, Ga, Tl, Ru, Re, and Os in a total content of 0.05 to 3.0 atomic percent on the surface of the TaN layer by a sputtering method.

6. The production method according to claim 5, wherein the wiring gutters or the interlayer connective channels are 0.15 μm or less in width and the ratio of the depth to the width (depth/width) is one or more; and the Cu layer is embedded into the wiring gutters or the interlayer connective channels covered with the TaN layer by applying heat after formation of the Cu layer.

7. The production method according to claim 5, wherein the wiring gutters or the interlayer connective channels are 0.15 μm or less in width and the ratio of the depth to the width (depth/width) is one or more; and the Cu layer is embedded into the wiring gutters or the interlayer connective channels covered with the TaN layer by applying heat and pressure after formation of the Cu layer.

8. A method for producing a Cu wire in a semiconductor device, comprising:
forming a TaN layer on the surfaces of wiring gutters or interlayer connective channels formed in an insulating film on a semiconductor substrate;
forming a Cu layer comprising Cu and one or more elements selected from the group consisting of Pt, In, Ti, Nb, B, Fe, V, Zr, Hf, Ga, Tl, Ru, Re, and Os in a total content of 0.05 to 3.0 atomic percent on the surface of the TaN layer by a sputtering method; and
forming a pure Cu layer on the surface of the Cu layer.

9. The production method according to claim 8, wherein the wiring gutters or the interlayer connective channels are 0.15 μm or less in width and the ratio of the depth to the width (depth/width) is one or more; and the pure Cu layer is embedded into the wiring gutters or the interlayer connective channels covered with the Cu layer by applying heat after formation of the pure Cu layer.

10. The production method according to claim 8, wherein the wiring gutters or the interlayer connective channels are 0.15 μm or less in width and the ratio of the depth to the width (depth/width) is one or more; and the pure Cu layer is embedded into the wiring gutters or the interlayer connective channels covered with the Cu layer by applying heat and pressure after formation of the pure Cu layer.
